(19) United States
(12) Patent Application Publication
(10) Pub. No.: US 2011/0122567 A1
(43) Pub. Date: May 26, 2011

(54) SURFACE COATING FOR HARD DISK DRIVE CAVITY

(75) Inventors: Li Kang Cheah, The Madeira (SG); Kenneth Donald Wing, Santa Cruz, CA (US); Say Leong Chan, Singapore (SG)

(73) Assignee: SPN INTERNATIONAL PTE LTD

(21) Appl. No.: 12/919,222

(22) PCT Filed: Feb. 25, 2009
(86) PCT No.: PCT/SG09/00065

§ 371 Date: Dec. 17, 2010

(30) Foreign Application Priority Data
Feb. 25, 2008 (SG) 200801587-7

(51) Int. Cl. H05K 5/00; B05D 7/22

(52) U.S. Cl. 361/679.33; 427/237

(57) ABSTRACT

A hard disk drive (HDD) case having a cavity configured to locate a HDD assembly therein, the cavity being coated with a coating characterized in that the center line average roughness (Rₐ) of the coated surface is 100 nm or less.

### TECHNICAL FIELD

This invention relates to the application of functional coatings to components with exposed surfaces within the clean cavity of the hard disk drive (HDD) such as head disk assembly (HDA) for increased reliability by lowering the number and size of free, third body particles.

### BACKGROUND

The HDA clean cavity contains various components including one or more components with a magnetic coating for storage of data, referred to as media, and one or more recording heads, referred to as head, for the writing and retrieval of the data onto and from the media. Coatings of diamond like carbon (DLC) are being applied to the head and the media to improve the wear characteristic by reducing the friction between these components with are moving relative to each other. In particular, the spacing between the media and the head is only a few angstroms. The head and the media move relative to each other. Any free particle on the surface of the media has a finite probability to cause damage to either the head or the media. This damage may result in the loss of data. The source of these free particles is the other components with exposed surfaces within the HDA.

The development of the technology of HDD supporting increases in aerial density over the past sixty years require that the head and media spacing be reduced. The reduction in the head and media spacing results in small particles of sub-micron dimensions having a higher likelihood of causing damage. Additionally, the introduction of perpendicular recording technology into the HDD has required changes to the media, resulting in the magnetic coatings on the media being susceptible to damage from any free particles within the HDA. Previously any hard particle from a metallic component had a much higher likelihood of resulting in damage to the media or head. In HDD using perpendicular recording technology, any free particle, including organic materials from both inorganic and organic materials, have the likelihood of causing damage to the media similar to a metallic particle on the older longitudinal recording media.

Current HDDs suffer from particle contamination during the operation and lead to short life span of HDD. Particles are generated from surfaces that expose to the air that circulate in high speed within the HDD enclosure. The turbulent air causes the particles to scatter on the media surfaces and lead to early failure of the head and media interface which the flight height is just in terms of few nanometers in height. Hard particles are one of the main causes for such failure.

One of the possibilities is the hard particle generated from the inner surface of HDD enclosure and the components that within the HDD that form the HDA. Most of the surfaces, even though are highly polished or smooth, may be sources for the generation of particles through the external static attraction of dust or loose particles generated from the surfaces. An additional cause for particles to loosen from the exposed internal surfaces within the HDD is moisture or humidity within the ambient air.

The largest areas exposed and able to generate particles are the base plate and the top cover. Both are typically either electroless nickel plated (EN plated) or electro-coating (e-coating). For current 1.8″ HDD, the top cover and base plate are usually EN plated. FIG. 1A-B show the SEM morphology 2,4 of EN coated stainless steel base plated. FIGS. 1A and 1B shows SEM micrographs 2,4 of electroless nickel plating (EN). As shown in FIG. 1A, some areas of the coated surfaces consist of loosely adhered particles 8, in this sample shown in FIG. 1A Ni(P) particles. The loose particles might fall off during the HDD operation. The particles remain in the HDD and likelihood that particle drop on the media surfaces and cause damages between the head and media during the spinning in high speed. FIG. 2A-2C shows schematic diagrams 40,50,52 of particle generation form a surface such as an EN layer. The EN grow mechanism is originated from islands that form in the EN layer, where the islands form grains 44 and grain boundaries 44, as shown in the diagram 40 of FIG. 2A. FIG. 2B shows in diagram 50 the weak point 46 of the EN failure contributed for degradation over time due to humidity or a weak link. FIG. 2C shows in diagram 52 loose and hard free particles 48 created that potentially could cause damage.

Attempts have been made to reduce risk of damage to the head or media. One attempt is to position a high efficiency filter within the HDA cavity to remove the free particles during operation. However, the filter is only effective on a small percentage of the air flowing between the head and media. Thus, the source of these free particles has to be treated so as to slow down the release of the particles before the reliability is improved.

As of now, there are two coatings for the motor base and the top cover components. One of the coatings uses is electrocoating of paint (e-coating) with a thickness between 4,000 and 10,000 nanometers (4 to 10 microns). The advantage of e-coating is the cost. The disadvantages of e-coating are control of Sn outgassing, scratch resistance, non-conducting, cleanliness and ability to remove particles from the surface during cleaning. The other coating is electroless nickel plating (EN) coating with a minimum thickness of 5,000 nanometers (5 microns) and maximum thickness up to 60,000 nanometers (60 microns). The disadvantages of EN coatings are cost, quality control for adhesion, cleanliness, and ability to remove particles form the surface during cleaning. The voice coil magnet with associated pole and the disk clamp are typically coated with EN. The voice coil wire is insulated with uncoated PVC (polyvinylchloride). The other aluminum and steel parts are only chemically passivated and the plastic parts are typically uncoated.

Previously, contamination within the HDA is managed by cleaning of the components of the HDA and subsequently handing these components in clean rooms. Components with common coatings such as electroless nickel plating and electrical paint deposition (e-coatings) are subjected to multiple cleaning cycles including detergents, ultrasonic washes, and rinses with DI water. Improvements to the cleanliness of the HDA components is by increasing the number of cleanings and rinse cycles, using sprays, and improving detergents. The clean rooms assembly's requirements have been improved. Hence, now the HDA components are handled in clean bags, moved in clean containers, and are assembled in environment near to Class 1. Class 1 is the clean room classification where the particle counts do not exceed a total of 3000 particles/m³ of a size of 0.5 μm (micron) or greater. The greatest particle present in any sample typically does not exceed μm (micron).

These attempts to improve are unable to meet the required HDA cleanliness of the current HDD technology. Particle contamination within the HDA is resulting in consumer data loss. The technology being used to manage data loss such as RAID systems and/or data back-up and recovery systems are both expensive and difficult to manage.

Within the HDA, a ramp is incorporated to remove the head from contact with the media during non use. Removing the head from the media provides the capability for the HDD to experience high shock levels with a lower likelihood of data loss or decrease in reliability. The ramp generates fine particles during the process of lifting the head off the media and again when loading the head onto the media.

Existing methodology that is used to prepare, and to clean the components with surfaces exposed interior to the HDA is no longer capable to meet current new product requirements. There is thus a need to minimize such problem and incident and thus to increase the mean time between failure (MTBF) of the HDD. There is a need for a new methodology to reduce the number of small particles, for example, 0.05 micron size and smaller.

### SUMMARY

According to a first aspect, there is provided a hard disk drive (HDD) case having a cavity configured to locate a HDD assembly therein, the cavity being coated with a coating characterized in that the center line average roughness (Rₐ) of the coated surface is 100 nm or less.

Advantageously, the coated surface having a Rₐ of 100 nm or less is a very smooth surface and hence the coating surface reduces the number of free particles that adhere to said cavity.

Advantageously, the roughness of the surface of the coating is less than the roughness of a coating that has been formed in an Electrocoating (“E-coat”) step. Hence, the smoothness of the coating in the disclosed first aspect is greater than the smoothness of a coating that has been formed in an E-coat step.

Advantageously, the roughness of the surface of the coating is less than the roughness of a coating that has been formed in electroless nickel (“EN”) coating step. Hence, the smoothness of the coating in the disclosed first aspect is greater than the smoothness of a coating that has been formed in an EN coat step.

In one embodiment, there is provided a hard disk drive (HDD) case having a cavity configured to locate a HDD assembly therein, the cavity being coated with a coating characterized in that the center line average roughness (Rₐ) of the coated surface is less than about 80 nm, preferably less than about 50 nm, more preferably less than 25 nm.

In one embodiment, there is provided a hard disk drive (HDD) case having a cavity configured to locate a HDD assembly therein, the cavity being coated with a coating that has been formed by a method selected from the group consisting of an aerosol deposition method, a sputtering method, a chemical vapor deposition method, and a sol-gel method, and wherein the center line average roughness (Rₐ) of the surface of the coating is 100 nm or less.

According to a second aspect, there is provided a method of coating a hard disk drive (HDD) case having a cavity configured to locate a HDD assembly therein, the method comprising the step of forming coating on the surface of the cavity such that the center line average roughness (Rₐ) of the surface of the coating is 100 nm or less. In one embodiment, the forming step is selected from the group consisting of an aerosol deposition method, a sputtering method, a chemical vapor deposition method, and a sol-gel method.

According to a third aspect, there is provided a coated hard disk drive case, the coating of the case having been formed from a sol-gel, wherein said sol-gel comprises at least one of a metal alkoxide or a metal halide; and wherein said coating is capable of reducing the number of free particles that adhere to thereon.

In one embodiment, there is provided a coated hard disk drive case, the coating of the case having been formed from a sol-gel containing at least one of a metal alkoxide and a metal halide disposed in a polymerizable media, and wherein upon polyermisation of the sol-gel, the center line average roughness (Rₐ) of the surface of the coating is 100 nm or less to thereby reduce the number of free particles that adhere to the surface of the case.

In one embodiment, there is provided an organic-inorganic coating for coating a hard disk drive, the coating comprising:

at least one of a metal alkoxide or a metal halide,

wherein said coating is capable of decreasing the number of free particles and limiting the size of the free particles that contaminate the hard disk drive. In one embodiment, the coating further comprises inorganic nano-particles or micro-particles. In another embodiment, the coating further comprises at least one of carbon nano-particles or carbon nanotubes.

In one embodiment, there is provided a method of reducing contamination in a hard disk drive comprising the step of applying a coating as disclosed herein to the hard disk drive.

In one embodiment, there is provided a hard disk drive (HDD) having a base, a cover, and a head disk assembly having hard disk drive components, the base, cover and components having surfaces defining a disk drive cavity, the surfaces being coated with a coating to decrease the number of free particles and limit the size of the free particles that contaminate the head disk assembly.

In another embodiment, there is provided a method of reducing contamination in a hard disk drive (HDD), the hard disk drive having a base, a cover, and a head disk assembly having hard disk drive components, the base, cover and components having surfaces defining a disk drive cavity, coating a surface in the disk drive cavity with a coating to decrease the number of free particles and limit the size of the free particles that contaminate the head disk assembly.

In one embodiment, the coating comprises a single layer. The coating may comprise multiple layers. The coating may be applied with wet chemical deposition or physical vapor deposition. The coating may comprise hybrid layers, wherein the coating is applied with a wet chemical deposition and physical vapor deposition.

In an embodiment, the coating may comprise nanoparticles. The coating may be nonconductive with, for example, at least 10⁹ Ohm-cm resistivity. The coating may be antistatic with, for example, 10³ Ohm-cm to 10⁹ Ohm-cm resistivity. The coating may be conductive with, for example, 10⁻⁶ Ohm-cm to 10 Ohm-cm resistivity.

In an embodiment, the coating may be applied to any metallic component for the purpose of protecting the component from corrosion. The coating may be applied to any component to improve the component's anti-static characteristics. The coating may be applied to any component to increase the component's electrical conductivity. The coating may be applied to any component to increase the head disk assembly overall electro-magnetic shielding characteristic. The coating may be applied in a process that integrates ultrasonic cleaning process immediately before coating deposition and in the same controlled environment. The coating may be applied in a process that integrates an in-line interlocking system of clean environments including an environment for the deposition of the coating.

In an embodiment, the head disk assembly comprises a ramp and a mating assembly, the coating applied to the ramp for the reduction of particles generated during sliding of the mating part on the ramp. The coating may be applied to the mating part. The coating may be applied to the hard disk drive motor base component with exposed surfaces within the hard disk assembly that reduces the number of potential particles on the surface of the component, and provides for the removal of particles with higher efficiency during cleaning. The coating may be applied to the hard disk drive motor components with exposed surfaces within the hard disk assembly that reduces the number of potential particles on the surface of the component, and provides for the removal of particles with higher efficiency during cleaning. The coating may be applied to the hard disk drive top cover with exposed surfaces within the hard disk assembly that reduces the number of potential particles on the surface of the component, and provides for the removal of particles with higher efficiency during cleaning. The coating may be applied to the hard disk drive latch and latch assembly with exposed surfaces within the hard disk assembly that reduces the number of potential particles on the surface of the component, and provides for the removal of particles with higher efficiency during cleaning. The coating may be applied to the hard disk drive ramp assembly with exposed surfaces within the hard disk assembly that reduces the number of potential particles on the surface of the component, and provides for the removal of particles with higher efficiency during cleaning. The coating may be applied to the hard disk drive voice coil assembly with exposed surfaces within the hard disk assembly that reduces the number of potential particles on the surface of the component, and provides for the removal of particles with higher efficiency during cleaning.

In an embodiment the coating is a thin layer film of nanometer thickness or micrometer thickness. The coating may be applied on an electroless nickel (EN) plating layer.

### DEFINITIONS

The following words and terms used herein shall have the meaning indicated:

The term “surface roughness” means unevenness or ruggedness present of the surface of an object at narrow spacing. Standard measurement and evaluation of these surfaces have been accepted in the United States as defined in American Standards Association Document B.46.1-1962, entitled “Surface Texture.” The terminology used in discussing surface texture uses such terms as “roughness,” “waviness,” “roughness-width cutoff,” “lay,” and “flaws.” Document B46.1-1962 also describes a measurement technique for evaluating the surface wave form to arrive at the arithmetic-average (AA), which is also referred to as “center line average” (CLA).

The term “liquid particle count” or LPC in the context of this specification refers to a numerical measurement of the quantity and size of particles in in-situ or flowing liquids. Such measurements can be obtained using a commercially available Liquid Particle Counter.

The term “free particle” in the context of this specification means a particle that is capable of being physically adhered or stuck to the surface of a hard disk drive case but which may be detached upon application of a force (ie such as by wiping the particles away from the case).

The term “chalcogen” is to be interpreted broadly to refer to atoms of Group VIA of the Periodic Table of Elements. More particularly, the term “chalcogen” includes elements selected from the group consisting of oxygen (O), sulfur (S), selenium (Se), and tellurium (Te).

The term “chalcogenide” is to be interpreted broadly to refer to a binary or multinary compound containing at least one chalcogen and at least one electropositive element or radical.

The term “metal chalcogenide” is to be interpreted broadly to refer to a chalcogenide in which the at least one electropositive element is a metal cation.

The term “nano-sized” as used herein relates to an average particle size of less than about 1000 nm, particularly less than about 200 nm, more particularly between about 1 nm to about 100 nm.

The term “micro-sized” as used herein, unless specified, relates to an average particle size of between about 1 μm to about 100 μm.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### DETAILED DESCRIPTION OF EMBODIMENTS

Exemplary, non-limiting embodiments of hard-disk drive case having a cavity configured to locate a HDD assembly therein, the cavity being coated with a coating characterized in that the center line average roughness (Rₐ) of the coated surface is 100 nm or less, will now be disclosed. In one embodiment, the hard-disk drive case is an aluminum case.

The coating may be formed by a method selected from the group consisting of an aerosol deposition method, a sputtering method, a chemical vapor deposition method, and a sol-gel method. In one embodiment, the sol gel method is used to coat the cavity of the HDD assembly. Advantageously, the sol-gel method when carried out with the coating described herein, produces a coating which is smoother than a conventional coating that has been formed in an E-coat step or a EN plating step (which are generally adopted in hard disk industries). While not being bound by theory, it is believed that because the coated surface formed using the sol gel method has a center line average roughness (Rₐ) of 100 nm or less, free particles having a size of 0.1 microns or larger would be less likely to be trapped on the surface irregularities of the coated surface. In one embodiment, free particles having a size from of from about 0.3 micron to about 1 micron is not able to adhere to the coated surface. In one embodiment, the center line average roughness (Rₐ) of the coated surface is less than about 80 nm, preferably less than about 50 nm, more preferably less than 25 nm. In one embodiment, the Rₐ of the coating is in the range of 1 nm to 100 nm or from 1 nm to 50 nm or from 1 nm to 25 nm or from 1 nm to 10 nm or from 10 nm to 100 nm or from 25 nm to 100 nm or from 50 nm to 100 nm.

When the sol-gel method is used, it is also preferably that the coating comprises at least one of a metal alkoxide, metal oxide, a metal halide, a poly-carbon compound containing a metal and/or silicon, or mixtures thereof. Preferably, the precursors used in the sol-gel method disclosed herein are metal alkoxides and metal halides such as metal chloride. The precursors usually undergo hydrolysis to form a gel-like substance that can be used to coat the HDD cavity. Upon coating, the gel-like substance is then dried to produce a densified coating material on the HDD cavity surface.

In one embodiment, the coating disclosed herein is formed as a continuous layer of film over the surface to be coated and is not porous. Advantageously, the continuity of the coating layer significantly reduces the likelihood of free particles being trapped on the coated surface.

The coating for coating a hard disk drive cavity may comprise nano-particles or micro-particles. The nano-particles may be organic, inorganic or a mixture of both organic and inorganic nanoparticles. Advantageously, the nano-particles or micro-particles may be added to increase the hardness and/or conductivity of the coating.

In one embodiment, the sol-gel from which the coating is formed has nano-particles and/or micro-particles contained therein.

In one embodiment, the coating is an organic-inorganic coating and may comprise at least one of a metal alkoxide, metal oxide or a metal halide, wherein said coating is capable of decreasing the number of free particles and limiting the size of the free particles that contaminate the hard disk drive.

In another embodiment, the coating further comprises at least one inorganic nano-particle. In yet another embodiment, the coating further comprises at least one of carbon nano-particles or carbon nanotubes,

The metal alkoxide disclosed herein may be selected from the group consisting of silicon alkoxide, titanium alkoxide, germanium alkoxide and aluminum alkoxide. In one embodiment, the metal alkoxide is selected from a group consisting of tetraethoxysilane, tetramethoxysilane, methyl-triethoxysilane, 1,2-Bis(trimethoxysilyl)ethane, silicon tetraisomyloxide, aluminum butoxide, aluminum isopropoxide, tetraethyl orthosilicates and combinations thereof. The metal alkoxide of the coating may be from about 10 weight percent to about 90 weight percent of the coating, from about 20 weight percent to about 80 weight percent of the coating, from about 30 weight percent to about 70 weight percent of the coating, from about 40 weight percent to about 60 weight percent of the coating, or from about 50 weight percent to about 90 weight percent of the coating.

The metal halides disclosed herein may include metal fluoride, metal bromide, metal chloride and metal iodide and mixtures thereof. The metal halides of the disclosed coating may be from about 10 weight percent to about 90 weight percent of the coating, from about 20 weight percent to about 80 weight percent of the coating, from about 30 weight percent to about 70 weight percent of the coating, from about 40 weight percent to about 60 weight percent of the coating, or from about 50 weight percent to about 90 weight percent of the coating.

Exemplary metals of the metal alkoxide, metal halide or inorganic nanoparticles may include, but are not limited to, Mg, Ca, Sr, Ba, Ag, Zn, Fe, Cu, Co, Al, Ce, Sn, Zr, Nb, Ti and Cr.

The inorganic nanoaparticles disclosed herein may be metal, metal chalcogenides, charcoal, carbon, silicon, mixtures thereof or any other semiconductor component known to those skilled in the art. The metal chalcogenides may be selected from the group consisting of ZnS, ZnSe, ZnTe, PbS, PbSe, PbTe, CuS, CuSe, CuTe, CdS, CdSe, CdTe, MnS, MnSe, MnTe, Ag₂S, Ag₂Se, Ag₂Te, ZnO, TiO₂, CeO₂, SnO₂, Fe₃O₄, Fe₂O₃, ZrO₂, CuO, MnO₂, Cu₂O, Al₂O₃, V₂O₃, Nb₂O₅, NiO, InO₃, HfO₂, Cr₂O₃, Ta₂O₅, Ga₂O₃, Y₂O₃, MoO₃, MgO, CaO, BaO, TiO₂, SrO, ZnO, Mn₂O₃, Fe₂O₃, FeO, ZrO₂, V₂O₃, V₂O₅, CuO, NiO, Al₂O₃, SiO₂, ZnO, Ag₂O, mixed metal oxides such as MgO/Al₂O₃ and CO₃O₄.

In one embodiment, the disclosed metal oxide particles are selected from the group consisting of MgO, CaO, BaO, TiO₂, SrO, ZnO, Mn₂O₃, Fe₂O₃, FeO, ZrO₂, V₂O₃, V₂O₅, CuO, NiO, Al₂O₃, SiO₂, ZnO, Ag₂O, mixed metal oxides such as MgO/Al₂O₃ and their mixtures thereof. The metal oxide particles may be coated or uncoated. In another embodiment, the inorganic nano-particles are selected from the group consisting of Zn nano-particles, Ti nano-particles, Cr nano-particles, Cu nano-particles, Au nano-particles, Pt nano-particles, TiO₂ nano-particles and Al₂O₃ nano-particles.

The inorganic nano-particles or carbon nano-particles may have an average particle size of about 10 nm to about 200 nm; about 10 nm to about 20 nm; about 10 nm to about 50 nm; about 10 nm to about 100 nm and about 50 nm to about 10 nm. The inorganic nano-particles of the disclosed coating may be from about 0 weight percent to about 5 weight percent of the coating, from about 0.5 weight percent to about 4 weight percent of the coating, from about 1 weight percent to about 3 weight percent of the coating, or from about 1.5 weight percent to about 2 weight percent of the coating.

In one embodiment, the carbon nano-particles and/or carbon nanotubes is from about 0 weight percent to about 20 weight percent of the coating, from about 5 weight percent to about 15 weight percent of the coating, from about 5 weight percent to about 10 weight percent of the coating, or from about 10 weight percent to about 15 weight percent of the coating. The coating may be applied to the hard disk drive by wet chemical deposition or by physical vapor deposition.

In one embodiment, the coating is conductive with 10⁻⁶ Ohm-cm to 10 Ohm-cm resistivity. Advantageously, when applied to the hard disk drive, the coating may increase the hard disk drive overall electro-magnetic shielding characteristics. More advantageously, when applied to the hard disk drive, the coating can also desirably increase the head disk assembly electrical conductivity.

In one embodiment, the coating is applied in a process that integrates ultrasonic cleaning process immediately before coating deposition in a same controlled environment. Advantageously, only one single environment is required in the production of the hard disk drive. In another embodiment, the coating is applied in a process that integrates an in-line interlocking system of clean environments comprising an environment for the deposition of the coating. Advantageously, this allows an in-line production of the hard disk drive.

The hard disk drive disclosed herein may comprise a base, a cover and a head disk assembly. Accordingly, the coating may be applied to at least one of the base, the cover and the head disk assembly.

The head disk assembly of the hard disk drive may also comprise a ramp and a mating assembly. In this case, the coating may also be applied to at least one of the ramp and the mating part to reduce the particles generated during sliding of the mating part on the ramp. Advantageously, this increases the head disk assembly overall electro-magnetic shielding characteristics.

The hard disk drive disclosed herein may further comprise a hard disk drive motor base component with exposed surfaces within the hard disk drive. In another embodiment, the hard disk drive further comprises a hard disk drive latch and latch assembly with exposed surfaces within the hard disk drive. In yet another embodiment, the hard disk drive further comprises a hard disk drive voice coil with exposed surfaces within the hard disk drive Application of the coating to the exposed surfaces of components described above allows reduction of the number of potential particles on the exposed surface of the component and allows the removal of particles from the component during cleaning to proceed with higher efficiency relative to an exposed surface which has not been coated with said coating. In one embodiment, the coating is applied on an electroless nickel (EN) plating layer.

The coating disclosed herein may be a single layer coating or a multiple layer coating. In one embodiment, at least one layer of the coating is a thin layer film in nanometer thickness. Accordingly, when the thin layer film is in nanometer thickness, the thickness of the thin layer film ranges from about 10 nm to about 100 nm, from about 20 nm to about 90 nm, from about 30 nm to about 80 nm, from about 40 nm to about 70 nm, or from about 50 nm to about 60 nm.

In another embodiment at least one layer of the coating is a thin layer film in micrometer thickness. Accordingly, when the thin layer film is in micrometer thickness, the thickness of the thin layer film ranges from about 1 microns to about 50 microns, from about 10 microns to about 40 microns, or from about 20 microns to about 30 microns.

The coating may also be used in a method of reducing contamination in a hard disk drive, comprising the step of applying the coating to the hard disk drive or its individual components.

### BRIEF DESCRIPTION OF DRAWINGS

In order that embodiments of the invention may be fully and more clearly understood by way of non-limitative example from the following description taken in conjunction with the accompanying drawings in that like reference numerals designate similar or corresponding elements, regions and portions, and in which:

FIG. 1A-1B show SEM morphology of EN coated surfaces;

FIG. 2A-2C show schematic diagrams of particle generation form a surface;

FIG. 3 shows expanded perspective views of components and assemblies with exposed surfaces within a head disk assembly (HDA) in accordance with an embodiment of the invention;

FIG. 4 shows a flow chart diagram of an embodiment of the invention;

FIG. 5 shows an OI surface coating in accordance with an embodiment of the invention;

FIG. 6A-6B show SEM morphology of EN coated surfaces applied in accordance with an embodiment of the invention; and

FIG. 7 shows a table showing the comparison of results achieved with a surface coating in accordance with an embodiment of the invention compared with a conventional process of cleaning without the surface coating in accordance with an embodiment of the invention.

FIG. 8A-8C show SEM morphology comparison between conventional EN coated surfaces (FIG. 8A), conventional E coated surface (FIG. 8B) and the coated surface in accordance with an embodiment of the invention; and

FIG. 9A-9B show SEM morphology comparison between an uncoated aluminum surface (FIG. 9A) and the coated surface of the aluminum surface in accordance with an embodiment of the invention (FIG. 9B).

### DETAILED DESCRIPTION

FIG. 3 shows expanded perspective views of components and assemblies with exposed surfaces within a HDD 10 in accordance with an embodiment of the invention. The HDD 10 comprises a first cover 12 and a second cover 32. The HDA comprises components such as spindle 14 for disk 24 and read/write heads 20 and actuator 22. The printed circuit cable 16 and base casting connects to the printed circuit board 30 via connector 26 and I/O connector 28. The internal components include spindle motor components, all of the HDA enclosures, recording head and recording media as well as the HDA. The HDA clean cavity contains various components including one or more components with a magnetic coating for storage of data, referred to as media, and one or more recording heads, referred to as head, for the writing and retrieval of the data onto and from the media. Application of coatings having nano-particles forming nano or micron films in accordance with an embodiment of the invention to the head and the media to improve the wear characteristic by reducing the friction between these components with are moving relative to each other. The surface to be coated may be defined as any surfaces (metal, plastic, ceramic, conductor, insulator, and the like) that expose to the environment (the surface interface with the air circulation) that housed the platter and read/write head inside the HDD. For example, base plate, top cover, spindle motor and spindle components to assemble the platter, latch and latch assemble, ramp assembly, voice coil, flexible printed circuit connectors and the like. The application of the coating reduces the number of particles that are generated from the surfaces during the operation of the HDD. The coating functionalities may further include adhesion, mechanical strength, corrosion resistant, antistatic discharged (ASD), and the like.

HDA may be defined as all the components housed within the HDD enclosure to form the essential parts for HDD excluded the PCBA. HDA may be defined as components to be the components that with any of the surfaces expose to the air that circulate within the enclosure during the operation.

For example, components include base plate, top cover, spindle motor and spindle components to assemble the platter, latch and latch assemble, ramp assembly, voice coil, flexible printed circuit, connectors, and the like. In general, all mechanical parts with metal or non-metal surface can be sources for loose particle generation.

Examples of the application of the coating in accordance with embodiments of the invention are discussed. An application in accordance with an embodiment of the invention is an Organic-Inorganic (OI) coating that may comprise, for example, the following mixture:
a. Metal alkoxides or metal chlorides where the Metal group may be Si, Ti and the like;
b. Inorganic nano-particles, for example, metal nano-particles, Zn, Ti, Cr, Cu, Au, Pt and etc and metal oxides, TiO₂, Al₂O₃ and others;
c. Carbon nano-particles or nanotubes;
d. Other additives and stabilizers known to those skilled in the art.
   The coating may be deposited by dipping, spraying, spinning and any method that suitable for wet chemical deposition. The solution may be formulated with different viscosity to suit for various deposition methods.

An application in accordance with an embodiment of the invention is a physical vapor deposition (PVD) or chemical vapor deposition coating that could be from any of deposition technology that about to offer continuous thin film with thicknesses of no more than 10 μm, preferable less than 5 μm and typically less than 2 μm. The coating shall be continuous, homogenous and dense (non-porous). The coating may be deposited, for example, by:
a. Magnetron sputtering or high power immersion sputtering with either linear or round shape that energized by either RF, mid frequency, DC pulsed, DC or other energy sources.
b. Evaporation that may be e-beam evaporation or thermal evaporation for both ceramic and metal coating.
c. Plasma enhanced, ECR or thermal CVD that able to deposit various metal and ceramic coating on metal and non-metal surfaces.
d. Arc or filtered arc that able to provide very dense and hard coating which possibly to deposit with as long particle as possible.
   Materials that may be deposited on the metal, semi-metal or insulator surface may be, for example Ti, Cr, Au, Pt, Ag, SiO₂, TiO₂, Al₂O₃, CrN, TiN, TiAlN, C, or the like. It will be understood that C could be in the form of graphite, amorphous diamond like carbon or nano-crystal diamond like carbon structure, metal containing carbon network, or the like. Basically, may be any hard coating that able to offer dense and continuous coating.

In an embodiment of the invention, a layer may comprise electrolytic or electroless plating with conductive metal or conductive metal with inclusion of polymer or polymer with inclusion of conductive nanosize metal particles.

Organic-Inorganic (OI) coatings having nanoparticles in accordance with an embodiment of the invention provide clean surfaces within hard disk drive (HDD) components. An application of functional coatings having nanoparticles that deposited to the Hard Disk Drive (HDD) enclosure inner surface and components that assemble the Head Disk Assembly (HDA) is disclosed. An application for the coating of HDD components, for example, within the head disk assembly (HDA) in general and to the use of coatings being a thin film of nanometer or micrometer thickness that may comprise nanoparticles on the individual components with surfaces exposed within the clean cavity of the HDD. The use of coatings in accordance with an embodiment of the invention increases the reliability of the HDD against data loss since the coatings have the properties of reducing the number and size of particles on the coated components and of improving the efficiency of removing particles deposited on the surfaces of the coated component using the industry's existing aqueous cleaning systems. The properties of the coatings are adjusted to improve the other surface properties of wear resistance, corrosion resistance, electrostatic efficiency, and conductivity. Multiple coatings may be used, one or more of which use nano-particles, to meet all of the HDD requirements, including an exterior coating for reduction in the number and size of particles within the HDA.

In an embodiment, the coating is the surface and structure of the thin film and may comprise amorphous or nano-size grains. The surface has little to no loose particles. The coating has sufficient adhesion and strength that is able to deposit to metals, ceramics and insulators. The coating may be conductive or with resistant qualities that provide anti-static discharged properties (10⁵ to 10⁸ Ohm-cm).

The organic-inorganic (OI) process for coatings in accordance with an embodiment of the invention may include for example, an initial OI coating is a nano-ceramics with organo-polysiloxane applied with a solvent base solution and in a dip coater. The initial coating may be a material such as with 24 wt % Silicon Oxide, 5 wt % resin, 32 wt % isopropyl alcohol (IPA), and 39 wt % Butyl Cellosolve (BCS). The part coated is a carbon steel base plate washed in a commercial aqueous based cleaning system using ultrasonic cleaning and Dl water. After rinsing and drying the component is further processed through a standard acid bath to etch the surface and remove all oxidation and loosely adhered particles. Further cleaning could use e-beam or other higher energy surface cleaning systems. The component is processed through a standard dip coater and oven cured at 40° C. for 20 minutes. After curing, the part is handled in a class 1,000 clean room and place sealed in clean bags. The coating thickness may be 1,000 and 2,000 nano-meters (1 to 2 microns).

This coating is cleaner than the existing industry coatings, showing LPC measurements of counts per sq inch of surface as shown in the table of FIG. 7. FIG. 7 shows a table 90 showing the comparison of results achieved with a surface coating in accordance with an embodiment of the invention 94,96 compared with a conventional process 92 of cleaning without the surface coating in accordance with an embodiment of the invention. The typical steel base plate with electroless nickel (EN) coating is measured as a control. The number of particles counted at 0.3 microns and below is 4,813 particles per sq inch of surface. The number of particles counted at 0.3 microns for the coated part is 1,732 particles, a 60% reduction in the number of particles shedding from the surface.

The particle count uses a commercial liquid particle counter, DI water, and ultrasonic to remove particles that are counted with a laser detector. The component is passed through the liquid particle counting process a number of times, until the counter detects a nearly constant reading from test to test. This reported number is a measure of the cleanliness of the surface. More importantly, the probability of media damage and data loss with the HDA is directly proportional to the number of particles released from the surface. A 60% reduction in the number of particles counter reflects a 60% decrease in the probability of data loss or a 60% increase in the reliability of the HDD for data loss due to a 3 body collision between the head, media, and a free particle.

An OI coating is used for the deposition of a coating meeting the stringent specification for cleanliness for parts within the HDA at a favorably low temperature which minimized the mechanical distortion and internal stress induced within the component material. The OI materials are used to make the coatings for the mechanical components within the HDA. Low cost dip coating equipment is used to deposit coatings on both metal and plastic parts for all components internal to the HDA.

FIG. 5 shows the application 70 of a coating 74 using OI nano-particles 72. The surface coatings deposited with OI nano-particles on a surface 76 within the HDA have characteristics of no loose or imbedded particles and easy cleaning in existing HDD aqueous ultrasonic equipment. Due to the nature of the coating, fine particles cannot be trapped temporarily and then released from small voids in the coatings. The OI process deposits closely packed small nano-particles onto the component surface 76. The nanostructure of the coating is controlled by the choice of coating material and the process parameters of solvents, time, and baking temperatures.

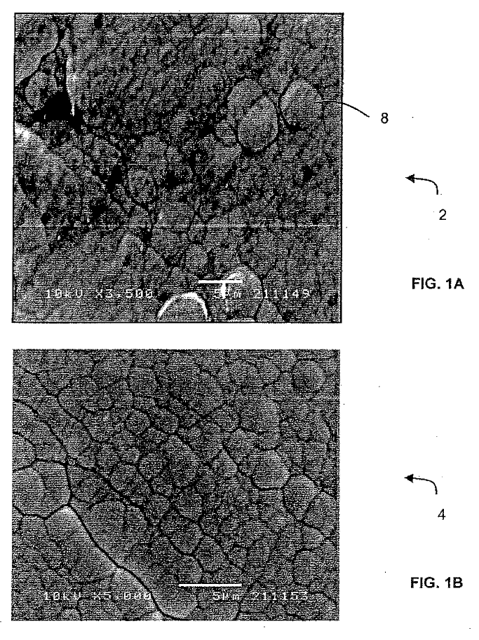

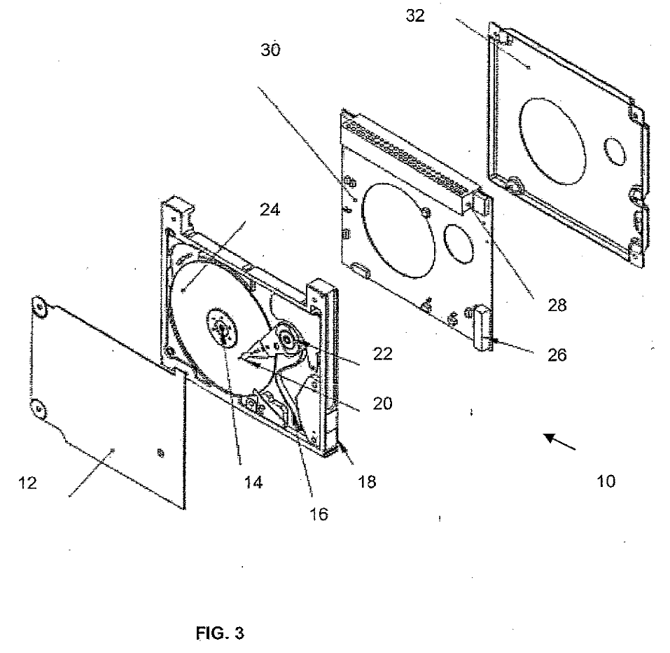

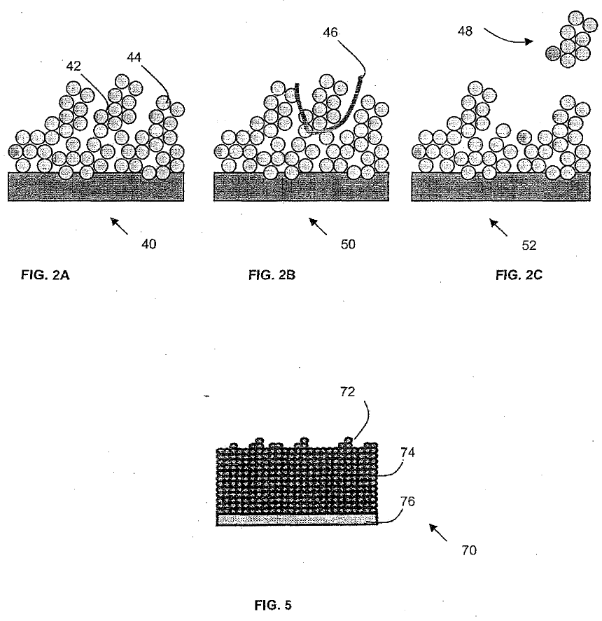

An example of the methodology in applying the coating in accordance with an embodiment of the invention is a combination of above coating methods to form a single or hybrid system coating on different surfaces and different parts to achieve better cleanliness. Cleanliness may be defined with readings and measures taken by the Liquid Particle Counter (LPC). The part to be measured is dipped into the Dl water with ultrasonic agitation. The part is washed several times until the particle value obtained is stable. A reading for example of a conventional EN plated 1.8″ base plate shows a final reading for the EN coated base plate is around 3000-6000 particle, for example 4768 (>0.3 μm)/cm². The quality of the coating could be fluctuating depending on the batches and subsequent HPA analysis revealed that there is presence of NiP particles corresponding to the EN coating. Such SEM micrographs are shown in FIG. 1A-1B of EN coated substrate as discussed.

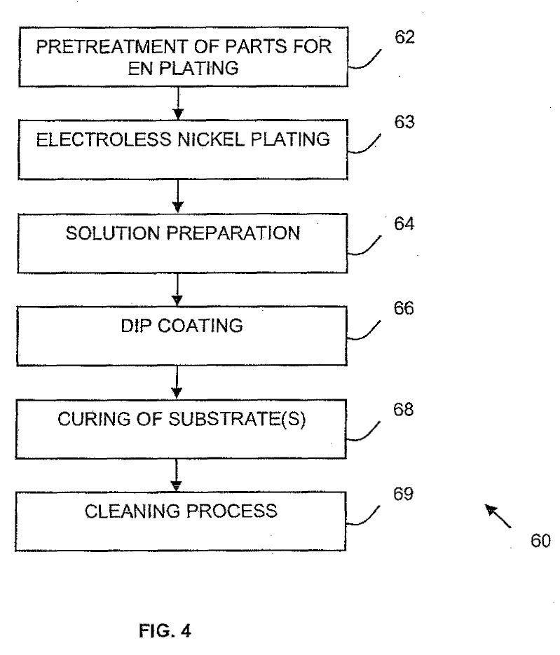

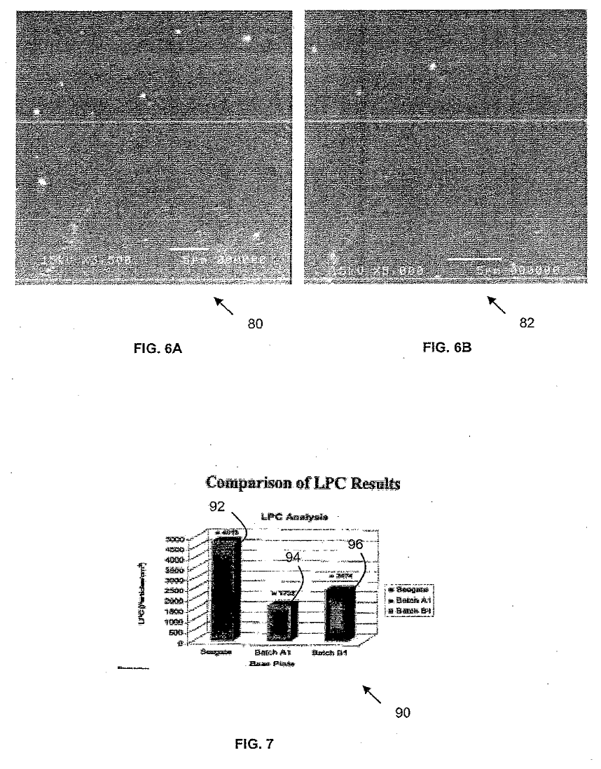

An example of an embodiment of the invention includes application of coating on base plates and top covers by aluminum or steel. The base plates and top covers typically manufactured by stamping and forming the dimension and shape. Some areas are machined to the specification. The part is treated with de-burring process to remove some shape edges. FIGS. 6A and 6B illustrate the SEM micrographs 80,82 of an organic-inorganic (OI) coated substrate at 3,500 magnification shown in FIG. 6A and at 5,000 magnification shown in FIG. 6B. In embodiments, single, multiple or hybrid layers may be deposited. In a single layer embodiment, the single layer may comprise a single OI layer coating. In a multi layer embodiment, the multi layer may comprise multiple OI layer coating, in a hybrid layer embodiment, the hybrid layer may comprise electroless or electroplating of metal, metal with polymer network or polymer with metal inclusion as base layer, such as electroless Ni or electroplating of Zn and follow by single or multiple layer of OI. One of the possible formulations 60 with EN as base layer and followed by single layer OI is shown in FIG. 4. Where layer 1 is a layer of electroless nickel plating (EN) where the process flow comprises pretreatment and EN plating 62, followed by electroless nickel plating 63, solution preparation 64, dip coating 66, curing of substrate(s) 68, and cleaning process 69. Before performing electroless nickel plating, the material to be plated must be cleaned by a series of cleaning chemicals such as bases and acids, this process is called the pre-treatment process of parts for EN plating. Failure to remove unwanted “soils” from the part's surface would result in poor plating. Each pre-treatment chemical must be followed by water rinsing (normally two to three times) to remove the chemical that adheres to the surface. Degreasing removes oils from surface; acid cleaning removes scaling. Activation is done with a weak acid etch, or nickel strike, or, in the case of non-metallic substrate, a proprietary solution. After the plating process, plated materials must be finished with an anti-oxidation or anti-tarnish chemical (trisodium phosphate, chromate etc) and pure water rinsing to prevent unwanted stains. The rinsing materials must then be completely dried off or sometimes baked off to obtain the full hardness of the plating film.

Electroless nickel plating is an auto-catalytic reaction used to deposit a coating of nickel on a substrate. The alloys with different percentage of phosphorus, ranging form 2-5 (low phosphorus) to up to 11-14 (high phosphorus) are possible. The metallurgical properties of alloys depend on the percentage of phosphorus.

In this embodiment layer 2, the OI layer, may comprise for example 20 ml of Methyl-trimethoxysilane, 0.6 ml of Sulphuric acid, 50 ml of De-ionized (Dl) water, 150 ml of Methanol, 0.05 grams of Polyvinyl pyrrolidone (PVP K30). Alternately metal/ceramic nanoparticles may be added. In the solution preparation in accordance with an embodiment of the invention the process flow may comprise metal/ceramic nanoparticles and PVP-300K are added into Dl water followed by ultrasonic stirring for 5 minutes. With stirring, concentrated sulphuric acid is added dropwise into the mixture, followed by addition of methyl-trimethoxysilane and allowed to ultrasonic for 30 minutes. Finally, methanol solvent is added and the mixture is allowed to mechanical stirred (˜600 rpm) for 20 minutes to achieve a homogeneous suspension.

Dip coating may comprise the following steps where the substrate is submerged into the above prepared mixture and held in the mixture for 2 to 5 seconds. Next, the substrate is withdrawn from the mixture and is rotated at room temperature for 1 minute. With the substrate rotating, hot air is applied to dry the substrate at about 100° C. for 5 minutes. The dried substrate is then cured in vacuum oven at 130 CC for 4 hours. Lastly, the substrate is then cleaned, dried and inspected.

Properties of the coating in an embodiment of the invention may comprise a thickness of preferably 50 nm-5 μm. The particle density with LPC method is preferably 200-2000 particles (>0.3 um)/cm². Under hard particles analysis (HPA), no trace of NiP particles is detected. In another embodiment, base plates and top covers may be coated by aluminum or steel where the base plates and top covers typically manufactured by stamping and forming the dimension and shape. Some areas are machined to the specification. The part may be treated with de-burring process to remove some shape edges. In embodiments, single, multiple or hybrid layers may be deposited.

In a single layer embodiment, the layer may comprise a single PVD layer coating. In a multi layer embodiment, the multi layer may comprise multiple PVD layer coatings with a mixture of materials or properties, such as Cr—Cu—Cr—Cu. or any metal, metal nitride or metal oxide combinations with each layer of 5 to 500 nm and final thickness of 50 nm to 5 μm. The layer may comprise a carbon network with different diamond (sp3) to graphite (sp2) ratio, such as high sp3, low sp3 multiple layer to form the final coating of 50 nm to 2 μm thickness.

Hybrid layers consist of electroless or electroplating of metal, metal with polymer network or polymer with metal inclusion as base layer, such as electroless Ni or electroplating of Zn and followed by a single or multiple layer of PVD coating. One embodiment of the possible formulations with EN as base layer and followed by single layer PVD is, for example the recipe comprises layer 1 being a electroless nickel plating (EN) base layer with a process flow including pretreatment and EN plating. As discussed, performing electroless nickel plating, the material to be plated must be cleaned by a series of cleaning chemicals such as bases and acids, this process is called the pre-treatment process. Failure to remove unwanted “soils” from the part's surface would result in poor plating. Each pre-treatment chemical must be followed by water rinsing (normally two to three times) to remove the chemical that adheres to the surface. Degreasing removes oils from surface; acid cleaning removes scaling. Activation is done with a weak acid etch, or nickel strike, or, in the case of non-metallic substrate, a proprietary solution. After the plating process, plated materials must be finished with an anti-oxidation or anti-tarnish chemical (trisodium phosphate, chromate etc) and pure water rinsing to prevent unwanted stains. The rinsing materials must then be completely dried off or sometimes baked off to obtain the full hardness of the plating film. Electroless nickel plating is an auto-catalytic reaction used to deposit a coating of nickel on a substrate. The alloys with different percentage of phosphorus, ranging form 2-5 (low phosphorus) to up to 11-14 (high phosphorus) are possible. The metallurgical properties of alloys depend on the percentage of phosphorus.

Layer 2 in this embodiment is a PVD coating where the PVD process comprises high immersion power sputtering may be used to deposit the seed layer to promote the adhesion between EN and PVD coating. Magnetron sputtering process is used to create the multilayer of Cr and Cu with each thickness of 10 nm each and final thickness of 1 μm. The properties of the layer may for example have a range of conductivity such as 10⁻⁶ to 10⁻⁴ Ohm-cm, with a thickness of 200 to 5 μm and a particle count of 200 to 2000 particles/cm².

In another embodiment of the invention, the application of the coating may be applied to polymer surfaces, for example base for arm assembly and voice coil and flexible circuitry. Coating may be applied for example using one of the following layers of hybrids of all:

1. OI coating with dipping, spraying or spinning method to offer a layer of coating on the plastic surfaces. The layer is able to offer the properties such as reducing the particle generation as well as to be anti-static to reduce the attraction of particle during the assembly. In additional, the additional layer of such coating may further prevent the static damage to the circuitry and head during the assembly and test. The resistivity of the coating may be adjusted from 10⁹ to 10⁵ Ohm-cm.

2. PVD coating to offer a layer of hard coating on the plastic surfaces. The layer is able to offer the properties such as reducing the particle generation as well as to be anti-static to reduce the attraction of particle during the assembly. In additional, the additional layer of such coating may further prevent the static damage to the circuitry and head during the assembly and test. The resistively of the coating may be adjusted from 10⁸ to 10⁻⁶ Ohm-cm

In another embodiment of the invention, the application of the coating may be applied to metal surfaces, for example, all aluminum, stainless steel surfaces, and the like. PVD coating could be applied to the surface to enhance the cleanliness and smoothness. The materials may comprise such materials as Cu, Cr, Ni, Ti, DLC (diamond like carbon), metal nitride, metal oxide. Embodiments may comprise multilayer structures or mixtures of the materials.

The OI process may deposit films with the required characteristic of cleanliness, hardness, durability, corrosion resistance, EMI shielding, no outgassing, scratch resistance, excellent adhesion, and conductivity as required by the HDD industry. These film coatings may be deposited on metal stampings and castings, and on plastics. In addition to pure elemental coatings, other compound coatings and coatings with doping may be developed to address current and future HDD requirements. One additional advantage of the process is that the raw components may be ultrasonically cleaned and dried within a controlled environment prior to coatings, keeping the entire process and coating materials free from contaminations.

The invention is susceptible of a variety of modifications. For example, other systems than the OI nano materials and dip coating equipment may be used to generate the coatings. Other components introduced into the HDA with exposed surfaces may be coated with this or similar coatings. Different or additional coating materials may be used to enhance or improve the properties of the coatings.

While the invention has been illustrated and described as embodied in a disk storage drive, it is not intended to be limited to the details shown, since various modifications and changes may be made without departing in any way from the spirit of the present invention. For example, the extension of the patent extends to all magnetic recording systems with relative movement between the recording Head and the recording Media.

A coating of the HDD voice coil assembly components with exposed surfaces within the HDA that reduces the number of potential particles on its internal surface, and provides for the removal of particles with higher efficiency during cleaning. The voice coil assembly components are the coil, the arm, the coil-arm assembly, the flex circuit assembly, the coil-arm-flex assembly, the flextures, the magnets, the pole, the magnet pole assembly, and all of the remaining components providing the for Head positioning function in the HDD.

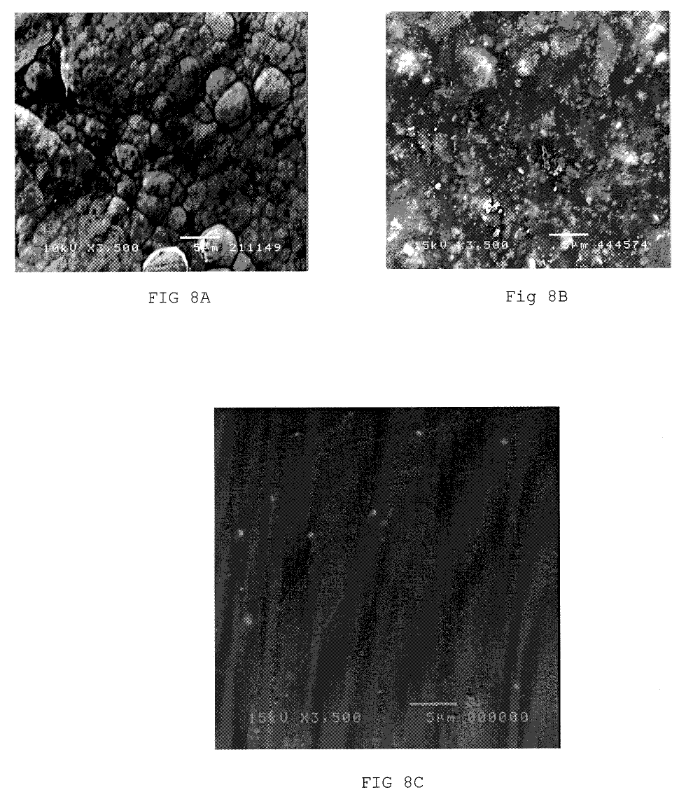

Referring to FIG. 8A-8C it can be seen that the coated surface in accordance to one embodiment disclosed herein (FIG. 8C) is smoother than the conventional EN coating (FIG. 8A) or E-coating (FIG. 8B) typically used in the hard disk industry. Advantageously, this translates to a lower likelihood of free particles adhering to the coated surface disclosed herein.

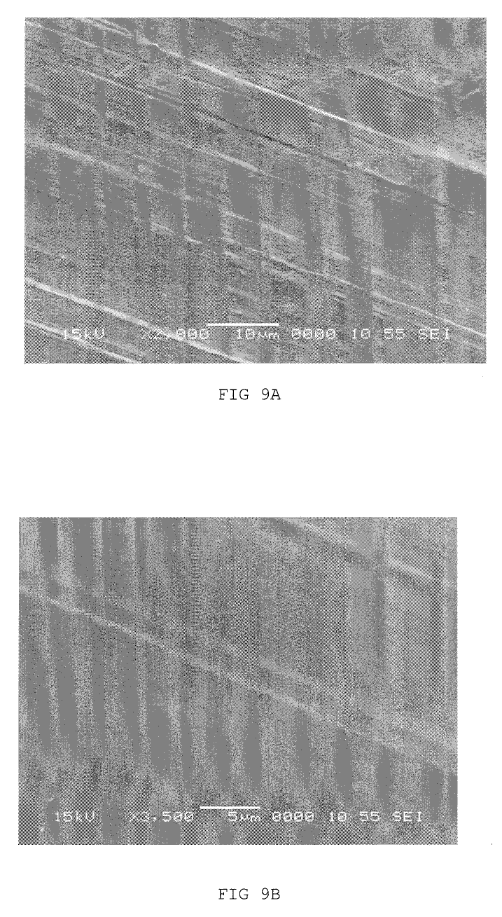

Referring now to FIG. 9A-9B, it can be seen that by coating the surface of aluminum by the coating disclosed herein, the coated surface of the aluminum (FIG. 9B) appears smoother than the case before it is coated (FIG. 9A). Again this indicates that the coating disclosed herein, improves the aluminum surface's ability to detach free-particles during cleaning, resulting in a much cleaner surface.

Without further analysis, the foregoing so fully reveal the gist of the present invention that others may, by applying current knowledge, readily adapt it for various applications without omitting features that, from the standpoint of prior art, fairly constitute essential characteristics of the generic or specific aspects of this invention.

While embodiments of the invention have been described and illustrated, it is to be understood by those skilled in the technology concerned that many variations or modifications in details of design or construction may be made without departing from the present invention.

1. A hard disk drive (HDD) case having a cavity configured to locate a HDD assembly therein, the cavity being coated with a coating characterized in that the center line average roughness (Rₐ) of the coated surface is 100 nm or less.

2. The case as claimed in claim 1, wherein the center line average roughness (Rₐ) of the coated surface is 50 nm or less.

3. The case as claimed in claim 2, wherein the center line average roughness (Rₐ) of the coated surface is 25 nm or less.

4. The case as claimed in any one of the preceding claims, wherein the coating is formed by a method selected from the group consisting of an aerosol deposition method, a sputtering method, a chemical vapor deposition method, and a sol-gel method.

5. The case as claimed in any one of the preceding claims, wherein the coating is comprised of a material selected from the group consisting of metal alkoxides, metal halide, metal oxides, metals, and carbon.

6. The case as claimed in any one of preceding claims, wherein the coating comprises a single layer.

7. The case as claimed in any one of claims 1 to 5, wherein the coating comprises multiple layers.

8. The case as claimed in claim 7, wherein coating comprises hybrid layers, wherein the coating is applied with a wet chemical deposition and physical vapor deposition.

9. The case as claimed in any one of the preceding claims, wherein the coating is nonconductive with at least 10⁹ Ohm-cm resistivity.

10. The case as claimed in any one of the preceding claims, wherein the coating is antistatic with 10³ Ohm-cm to 10⁹ Ohm-cm resistivity.

11. The case as claimed in any one of the preceding claims, wherein the coating is conductive with 10⁻⁶ Ohm-cm to 10 Ohm-cm resistivity.

12. The case as claimed in any one of the preceding claims, wherein the coating is applied in a process that integrates ultrasonic cleaning process immediately before coating deposition and in the same controlled environment.

13. The case as claimed in any one of the preceding claims, wherein the coating is applied in a process that integrates an in-line interlocking system of clean environments including an environment for the deposition of the coating.

14. The case as claimed in any one of the preceding claims, wherein the HDD assembly contains a head disk assembly, the head disk assembly comprises a ramp and a mating assembly, and wherein the coating applied to the ramp for the reduction of particles generated during sliding of the mating part on the ramp.

15. The case as claimed in claim 14, wherein the coating is applied to the mating part.

16. The case as claimed in any one of the preceding claims, wherein the coating is a thin layer film in nanometer thickness.

17. The case as claimed in any one of claims 1-16, wherein the coating is a thin film in micrometer thickness.

18. The case as claimed in any one of the preceding claims, wherein the coating is applied on an electroless nickel (EN) plating layer.

19. A method of coating a hard disk drive (HDD) case having a cavity configured to locate a HDD assembly therein, the method comprising the step of forming coating on the surface of the cavity such that the center line average roughness (Ra) of the surface of the coating is 100 nanometer or less.

20. The method as claimed in claim 19, wherein the forming step is selected from the group consisting of an aerosol deposition method, a sputtering method, a chemical vapor deposition method, and a sol-gel method.

21. The method as claimed in any one of claims 19-20, wherein the coating comprises a single layer.

22. The method as claimed in any one of claims 19-20, wherein the coating comprises multiple layers.

23. The method as claimed in claim 22, wherein the coating comprises hybrid layers, and wherein the coating is applied with a wet chemical deposition and physical vapor deposition.

24. The method as claimed in any one of claims 19-23, wherein the coating is nonconductive with at least 10⁹ Ohm-cm resistivity.

25. The method as claimed in any one of claims 19-24, wherein the coating is antistatic with 10³ Ohm-cm to 10⁹ Ohm-cm resistivity.

26. The method as claimed in any one of claims 19-25, wherein the coating is conductive with 10⁻⁶ Ohm-cm to 10 Ohm-cm resistivity.

27. The method as claimed in any one of claims 19-26, wherein the coating is applied in a process that integrates ultrasonic cleaning process immediately before coating deposition and in the same controlled environment.

28. The method as claimed in any one of claims 19-27, wherein the coating is applied in a process that integrates an in-line interlocking system of clean environments including a environment for the deposition of the coating.

29. The method as claimed in any one of claims 19-28, wherein the HDD assembly contains a head disk assembly, the head disk assembly comprises a ramp and a mating assembly, and wherein the coating applied to the ramp for the reduction of particles generated during sliding of the mating part on the ramp.

30. The method as claimed in claim 29, wherein the coating is applied to the mating part.

31. The method as claimed in any one of claims 19-30, wherein the coating is applied to a hard disk drive motor base component with exposed surfaces within the hard disk assembly that reduces the number of potential particles on the surface of the component, and provides for the removal of particles with higher efficiency during cleaning.

32. The method as claimed in any one of claims 19-31, wherein the case has a hard disk drive top cover with exposed surfaces within a hard disk assembly that reduces the number of potential particles on the surface of the component, and provides for the removal of particles with higher efficiency during cleaning.

33. The method as claimed in any one of claims 19-32, wherein the coating is a thin layer film in nanometer thickness.

34. The method as claimed in any one of claims 19-32, wherein the coating is a thin film in micrometer thickness.

35. The method as claimed in any one of claims 19-34, wherein the coating is applied on an electroless nickel (EN) plating layer.

36. A coated hard disk drive, the coating having been formed from a sol-gel, wherein said sol-gel comprises
at least one of a metal alkoxide and a metal halide disposed in a polymerizable media;
and wherein said coating is capable of reducing the number of free particles that adhere to thereon.

37. The coated hard disk drive as claimed in claim 36, wherein the sol-gel further comprises inorganic nano-particles.

38. The coated hard disk drive as claimed in any one of claims 36-37, wherein the sol-gel comprises at least one of carbon nano-particles or carbon nanotubes.

39. The coated hard disk drive as claimed in any one of the claims 36 to 38, wherein the metal alkoxide is selected from the group consisting of silicon alkoxide, titanium alkoxide, germanium alkoxide and aluminum alkoxide.

40. The coated hard disk drive as claimed in claim 39, wherein the metal alkoxide is selected from the group consisting of tetraethoxysilane, tetramethoxysilane, methyl-triethoxysilane, 1,2-Bis(trimethoxysilyl)ethane, silicon tetraisomyloxide, aluminum butoxide, aluminum isopropoxide, tetraethyl orthosilicates and combinations thereof.

41. The coated hard disk drive as claimed in any one of the claims 36-40, wherein the metal halide is selected from the group consisting of metal fluoride, metal bromide, metal chloride and metal iodide and mixtures thereof.

42. The coated hard disk drive as claimed in any one of claims 37-42, wherein the inorganic nano-particles are selected from the group consisting of Zn nano-particles, Ti nano-particles, Cr nano-particles, Cu nano-particles, Au nano-particles, Pt nano-particles, TiO₂ nano-particles and Al₂O₃ nano-particles.

43. The coated hard disk drive as claimed in any one claims 36-42, wherein the metal alkoxide is from 10 weight percent to about 90 weight percent.

44. The coated hard disk drive as claimed in any one of claims 36-43, wherein the metal halide is from 10 weight percent to 90 weight percent.

45. The coated hard disk drive as claimed in any one of claims 37-44, wherein the inorganic nano-particles is from 0 weight percent to 5 weight percent.

46. The coated hard disk drive as claimed in any one of claims 38-45, wherein the carbon nano-particles is from 0 weight percent to 20 weight percent.

47. The coated hard disk drive as claimed in any one of claims 38-45, wherein the carbon nanotubes is from 0 weight percent to about 20 weight percent.
